(19) United States
(12) Patent Application Publication
(10) Pub. No.: US 2007/0059554 A1
(43) Pub. Date: Mar. 15, 2007

(54) Organic electroluminescent device

(75) Inventor: Akira Takeda, Kanagawa (JP)

Correspondence Address: SUGHRUE-265550, 2100 PENNSYLVANIA AVE. NW, WASHINGTON, DC, 20037-3213, US

(73) Assignee: FUJI PHOTO FILM CO., LTD.

(21) Appl. No.: 11/519,864

(22) Filed: Sep. 13, 2006

(30) Foreign Application Priority Data
Sep. 13, 2005 (JP) P2005-265609

(51) Int. Cl. H01L 51/54

(52) U.S. Cl. 428/690; 428/917; 313/504; 313/506; 257/E51.05

(57) ABSTRACT

An organic electroluminescent device is provided and has at least one organic layer including a light-emitting layer between a pair of electrodes. The organic layer contains at least one compound represented by specific formula.

### BACKGROUND OF THE INVENTION

1. Field of the Invention

The present invention relates to an organic electroluminescent device which can emit light by converting electric energy into optical energy (hereinafter, also referred to as ‘organic EL device’, ‘light-emitting device’, or ‘device’), and particularly relates to an organic electroluminescent device excellent in emission characteristics and durability.

2. Description of Background Art

Currently, various display devices (organic light-emitting elements) using organic light-emitting materials have been intensively researched and developed, and an organic EL device is noticed as a hopeful display device among others because light can be emitted at high luminance at low voltage. For example, there is known an EL device in which an organic thin film is formed by deposition of an organic compound (for example, please refer to Applied Physics Letters, Vol. 51, pp. 913, 1987). An organic EL device described in that document has a layered structure of an electron transport material and a hole transport material. Accordingly, the organic EL device has a remarkably improved luminescence property as compared with a known single-layered device.

In recent years, in order to achieve high-efficiency elements, a phosphorescent material is used. As the phosphorescent material, iridium complexes and platinum complexes are known (for example, please refer to U.S. Pat. No. 6,303,238, WO 00/57676 and WO 00/70655.

In WO 00/70655, in the light-emitting layer, Ir (ppy) (tris (2-phenylpyridine) iridium) is used as a dopant, and CBP (4,4′-N,N′-dicarbazolebiphenyl) is used as a host material. However, the host material still requires improvement.

### SUMMARY OF THE INVENTION

An object of an illustrative, non-limiting embodiment of the present invention is to provide a light-emitting device having high emission luminance, high luminous efficiency, and excellent durability. Further, another object of an illustrative, non-limiting embodiment of the present invention is to provide a compound favorable for the light-emitting device.

The above-mentioned object can be accomplished by the following means.
(1) An organic electroluminescent device comprising:

a pair of electrodes; and

at least one organic layer between the pair of electrode, the at least one organic layer including a light-emitting layer, wherein the at least one organic layer contains a compound represented by formula (I): 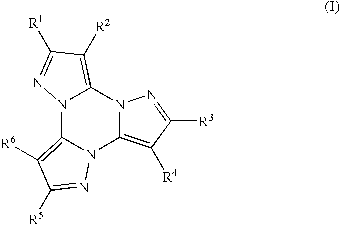
wherein R¹, R², R³, R⁴, R⁵, and R⁶ each independently represents a hydrogen atom or a substituent group; R¹ to R⁶ are same with or different from one another; when R¹ and R² are not hydrogen atoms, R¹ and R² may be bonded to each other to form a ring; when R³ and R⁴ are not hydrogen atoms, R³ and R⁴ may be bonded to each other to form a ring; and when R⁵ and R⁶are not hydrogen atoms, R⁵ and R⁶ may be bonded to each other to form a ring.
(2) The organic electroluminescent device according to (1) above, wherein R¹, R³, and R⁵ each independently represents an aryl group or a heteroaryl group.
(3) The organic electroluminescent device according to (1) above, wherein R², R⁴, and R⁶ each independently represents an aryl group or a heteroaryl group.
(4) The organic electroluminescent device according to any one of (1) to (3) above, wherein R¹ to R⁶ each independently represents an aryl group or a heteroaryl group.
(5) The organic electroluminescent device according to any one of (1) to (4) above, wherein the light-emitting layer contains the compound represented by formula (I).
(6) The organic electroluminescent device according to any one of (1) to (4) above, wherein the at least one organic layer includes at least one of an electron injecting layer and an electron transport layer, the at least one of the electron injecting layer and the electron transport layer contains the compound represented by formula (I).
(7) The organic electroluminescent device according to any one of (1) to (4) above, wherein the at least one organic layer includes at least one of a hole injecting layer and a hole transport layer, the at least one of the hole injecting layer and the hole transport layer contains the compound by formula (I).
(8) The organic electroluminescent device according to any one of (1) to (4) above, wherein the light-emitting layer contains at least one light-emitting material and at least two host materials, and at least one of the at least two host materials is the compound represented by formula (I).
(9) The organic electroluminescent device according to any one of (1) to (8) above, wherein the light-emitting layer contains at least one phosphorescent material, and the at least one organic layer contains the compound represented by formula (I).
(10) The organic electroluminescent device according to (9) above, wherein the light-emitting layer contains at least one metal complex having a tetradentate ligand as the phosphorescent material.

### DETAILED DESCRIPTION OF THE EXEMPLARY EMBODIMENTS

Although the invention will be described below with reference to the exemplary embodiments thereof, the following exemplary embodiments and modifications do not restrict the invention.

A light-emitting device according to an exemplary embodiment of the invention has high external quantum efficiency and maximum luminance, excellent luminescence property and durability. The light-emitting device can be used in the field of display devices, displays, backlights, electrophotography, illumination light sources, recording light sources, exposure light sources, reading light sources, indicators, signboards, interiors, optical communications, etc. Further, a compound according to an exemplary embodiment of the invention can be applied in a medical use, fluorescent whitening agents, photographic materials, UV absorbing materials, laser dyes, materials for recording media, colorants for inkjet, colorants for colorfilter, color conversion filters, etc. A novel complex according to an exemplary embodiment of the invention is preferable for manufacturing the above-described excellent light-emitting device.

An organic electroluminescent device (hereinafter, also referred to as ‘device of the invention’) of the invention includes at least one organic layer (it may be a layer formed of an organic compound, or an organic layer containing an inorganic compound) including a light-emitting layer between a pair of electrodes, in which the layer placed between the pair of electrodes contains a compound represented by formula (I).

The compound represented by formula (I) will be described.

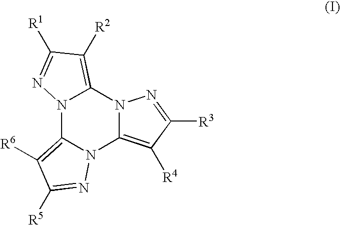

R¹, R², R³, R⁴, R⁵, and R⁶ each independently represents a hydrogen atom or a substituent group. Examples of the substituent group include, but are not limited to, an alkyl group, an alkenyl group, an alkynyl group, an aryl group, an amino group, an alkoxy group, an aryloxy group, a heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a heterocyclic thio group, a sulfonyl group, a sulfinyl group, a ureido group, a phosphoric acid amide group, a hydroxy group, a mercapto group, a halogen group, a cyano group, a sulfo group, a carboxyl group, a nitro group, a hydroxamic acid group, a sulfino group, a hydrazino group, an imino group, a heteroaryl group, a silyl group, a silyloxy group, and the like.

The alkyl group has preferably 1 to 30 carbon atoms, more preferably 1 to 20 carbon atoms, and most preferably 1 to 10 carbon atoms. Examples of the alkyl group include methyl, ethyl, n-propyl, iso-propyl, n-butyl, tert-butyl, n-octyl, n-nonyl, n-decyl, n-dodecyl, n-octadecyl, n-hexadecyl, cyclopropyl, cyclobutyl, cyclopentyl, cyclohexyl, cyclooctyl, 1-adamantyl, and the like.

The alkenyl group has preferably 2 to 30 carbon atoms, more preferably 2 to 20 carbon atoms, and most preferably 2 to 10 carbon atoms. Examples of the alkenyl group include vinyl, allyl, 1-propenyl, 1-isopropenyl, 1-butenyl, 2-butenyl, 3-pentenyl, and the like.

The alkynyl group has preferably 2 to 30 carbon atoms, more preferably 2 to 20 carbon atoms, and most preferably 2 to 10 carbon atoms. Examples of the alkynyl group include ethynyl, propargyl, 1-propynyl, 3-pentynyl, and the like.

The aryl group has preferably 6 to 30 carbon atoms, more preferably 6 to 20 carbon atoms, and most preferably 6 to 12 carbon atoms. Examples of the aryl group include phenyl, o-methylphenyl, m-methylphenyl, p-methylphenyl, 2,4-xylyl, p-cumenyl, mesityl, naphthyl, anthranyl, 4-methoxyphenyl, 4-diphenylaminophenyl, 4-cyanophenyl, and the like.

The amino group has preferably 0 to 30 carbon atom(s), more preferably 0 to 20 carbon atom(s), and most preferably 0 to 10 carbon atom(s). Examples of the amino group include amino, methylamino, dimethylamino, diethylamino, dibenzylamino, diphenylamino, ditolylamino, and the like.

The alkoxy group has preferably 1 to 30 carbon atom(s), more preferably 1 to 20 carbon atom(s), and most preferably 1 to 10 carbon atom(s). Examples of the alkoxy group include methoxy, ethoxy, butoxy, 2-ethylhexyloxy, and the like.

The aryloxy group has preferably 6 to 30 carbon atoms, more preferably 6 to 20 carbon atoms, and most preferably 6 to 12 carbon atoms. Examples of the aryloxy group include phenyloxy, 1-naphthyloxy, 2-naphthyloxy, and the like.

The heterocyclic oxy group has preferably 1 to 30 carbon atom(s), more preferably 1 to 20 carbon atom(s), and most preferably 1 to 12 carbon atom(s). Examples of the heterocyclic oxy group include pyridyloxy, pyradyloxy, pyrimidyloxy, quinolyloxy, and the like.

The acyl group has preferably 1 to 30 carbon atom(s), more preferably 1 to 20 carbon atom(s), and most preferably 1 to 12 carbon atom(s). Examples of the acyl group include acetyl, benzoyl, formyl, pivaloyl, and the like.

The alkoxycarbonyl group has preferably 2 to 30 carbon atoms, more preferably 2 to 20 carbon atoms, and most preferably 2 to 12 carbon atoms. Examples of the alkoxycarbonyl group include methoxycarbonyl, ethoxycarbonyl, and the like.

The aryloxycarbonyl group has preferably 7 to 30 carbon atoms, more preferably 7 to 20 carbon atoms, and most preferably 7 to 12 carbon atoms. Examples of the aryloxycarbonyl group include phenyloxycarbonyl and the like.

The acyloxy group has preferably 2 to 30 carbon atoms, more preferably 2 to 20 carbon atoms, and most preferably 2 to 10 carbon atoms. Examples of the acyloxy group include acetoxy, benzoyloxy, and the like.

The acylamino group has preferably 2 to 30 carbon atoms, more preferably 2 to 20 carbon atoms, and most preferably 2 to 10 carbon atoms. Examples of the acylamino group include acetylamino, benzoylamino, and the like.

The alkoxycarbonylamino group has preferably 2 to 30 carbon atoms, more preferably 2 to 20 carbon atoms, and most preferably 2 to 12 carbon atoms. Examples of the alkoxycarbonylamino group include methoxycarbonylamino and the like.

The aryloxycarbonylamino group has preferably 7 to 30 carbon atoms, more preferably 7 to 20 carbon atoms, and most preferably 7 to 12 carbon atoms. Examples of the aryloxycarbonylamino group include phenyloxycarbonylamino and the like.

The sulfonylamino group has preferably 1 to 30 carbon atom(s), more preferably 1 to 20 carbon atom(s), and most preferably 1 to 12 carbon atom(s). Examples of the sulfonylamino group include methanesulfonylamino, benzenesulfonylamino, and the like.

The sulfamoyl group has preferably 0 to 30 carbon atom(s), more preferably 0 to 20 carbon atom(s), and most preferably 0 to 12 carbon atom(s). Examples of the sulfamoyl group include sulfamoyl, methylsulfamoyl, dimethylsulfamoyl, phenylsulfamoyl, and the like.

The carbamoyl group has preferably 1 to 30 carbon atom(s), more preferably 1 to 20 carbon atom(s), and most preferably 1 to 12 carbon atom(s). Examples of the carbamoyl group include carbamoyl, methylcarbamoyl, diethylcarbamoyl, phenylcarbamoyl, and the like.

The alkylthio group has preferably 1 to 30 carbon atom(s), more preferably 1 to 20 carbon atom(s), and most preferably 1 to 12 carbon atom(s). Examples of the alkylthio group include methylthio, ethylthio, and the like.

The arylthio group has preferably 6 to 30 carbon atoms, more preferably 6 to 20 carbon atoms, and most preferably 6 to 12 carbon atoms. Examples of the arylthio group include phenylthio and the like.

The heterocyclic thio group has preferably 1 to 30 carbon atom(s), more preferably 1 to 20 carbon atom(s), and most preferably 1 to 12 carbon atom(s). Examples of the heterocyclic thio group include pyridylthio, 2-benzimizolylthio, 2-benzoxazolylthio, 2-benzothiazolylthio, and the like.

The sulfonyl group has preferably 1 to 30 carbon atom(s), more preferably 1 to 20 carbon atom(s), and most preferably 1 to 12 carbon atom(s). Examples of the sulfonyl group include mesyl, tosyl, trifluoromethane sulfonyl, and the like.

The sulfinyl group has preferably 1 to 30 carbon atom(s), more preferably 1 to 20 carbon atom(s), and most preferably 1 to 12 carbon atom(s). Examples of the sulfinyl group include methanesulfinyl, benzenesulfinyl, and the like.

The ureido group has preferably 1 to 30 carbon atom(s), more preferably 1 to 20 carbon atom(s), and most preferably 1 to 12 carbon atom(s). Examples of the ureido group include ureido, methylureido, phenylureido, and the like.

The phosphoric acid amide group has preferably 1 to 30 carbon atom(s), more preferably 1 to 20 carbon atom(s), and most preferably 1 to 12 carbon atom(s). Examples of the phosphoric acid amide group include diethylphosphoric acid amide, phenylphosphoric acid amide, and the like.

Examples of the halogen atom include a fluorine atom, a chlorine atom, a bromine atom, an iodine atom, and the like.

The heteroaryl group has preferably 3 to 30 carbon atoms, and more preferably 5 to 12 carbon atoms. Examples of the heteroatom include a nitrogen atom, an oxygen atom, and a sulfur atom. Specific examples of the heteroaryl group include imidazolyl, pyrazolyl, pyridyl, pyrazyl, pyrimidyl, triazinyl, quinolyl, isoquinolinyl, indolyl, furyl, thienyl, piperidyl, morpholino, benzoxazolyl, benzimidazolyl, benzothiazolyl, carbazolyl, azepinyl, and the like.

The silyl group has preferably 3 to 40 carbon atoms, more preferably 3 to 30 carbon atoms, and most preferably 3 to 24 carbon atoms. Examples of the silyl group include trimethylsilyl, triphenylsilyl and the like.

The silyloxy group has preferably 3 to 40 carbon atoms, more preferably 3 to 30 carbon atoms, and most preferably 3 to 24 carbon atoms. Examples of the silyloxy group include trimethylsilyloxy, triphenylsilyloxy, and the like.

As the substituent group, preferably, an alkyl group, an aryl group, a heteroaryl group, an acyl group, an amino group, a halogen group, and a cyano group, more preferably, an alkyl group, an aryl group, a heteroaryl group, an acyl group, and an amino group, and most preferably, a t-butyl group, a phenyl group, a 4-methoxyphenyl group, a 4-diphenylaminophenyl group, a 4-cyanophenyl group, a diphenylamino group, and a carbazolyl group can be exemplified. These substituent groups each may be further substituted with other substituent groups. The substituent groups may be bonded and form ring structures.

R¹, R², R³, R⁴, R⁵, and R⁶ may be same with or different from each other. Preferably, R¹, R³, and R⁵ are same with each other, or R², R⁴, and R⁶ are same with each other. More preferably, R¹, R³, and R⁵ are same with each other, and R², R⁴, and R⁶ are same with each other. Most preferably, R¹, R², R³, R⁴, R⁵, and R⁶ are the same.

In one embodiment, R¹, R³, and R⁵ each are preferably an aryl group or a heteroaryl group. In another embodiment, R², R⁴, and R⁶ each are preferably an aryl group or a heteroaryl group. In another embodiment, R¹ to R⁶ each are preferably an aryl group or a heteroaryl group.

The compound represented by formula (I) may be contained in a main chain or a side chain of a polymer or a polymer compound, such as a dendrimer. The compound is a single molecule that has preferably a molecular weight of 2000 or less, and more preferably 1000 or less.

The usage of the compound represented by formula (I) of the invention is not limited but may be contained in any layer of the organic layer. The compound is preferably contained in any one of a hole injecting layer, a hole transport layer, a light-emitting layer, an electron transport layer, an electrode injecting layer, an exciton blocking layer, and a charge blocking layer, or in a plurality of the above-mentioned layers. More preferably, the compound is contained in the hole transport layer, the light-emitting layer, and the electron transport layer. Most preferably, the compound is contained in the light-emitting layer.

In one embodiment, the compound represented by formula (I) is preferably contained in the electron injecting layer or the electron transport layer. In another embodiment, the compound represented by formula (I) is preferably contained in the hole injecting layer or the hole transport layer. In still another embodiment, the light-emitting layer preferably contains at least one light-emitting material and at least two host materials, and at least one of the host materials is preferably the compound represented by formula (I).

A light-emitting material used in the invention may be a fluorescent material or a phosphorescent material. A phosphorescent material using a metal complex is preferably used, more preferably, a metal complex containing iridium or platinum, and most preferably, a metal complex having a tetradentate ligand is used. Specifically, the compound described in WO 04/108857 is used.

Specific examples of the compound represented by formula (I) are exemplified below, but the invention is not limited to these compounds.

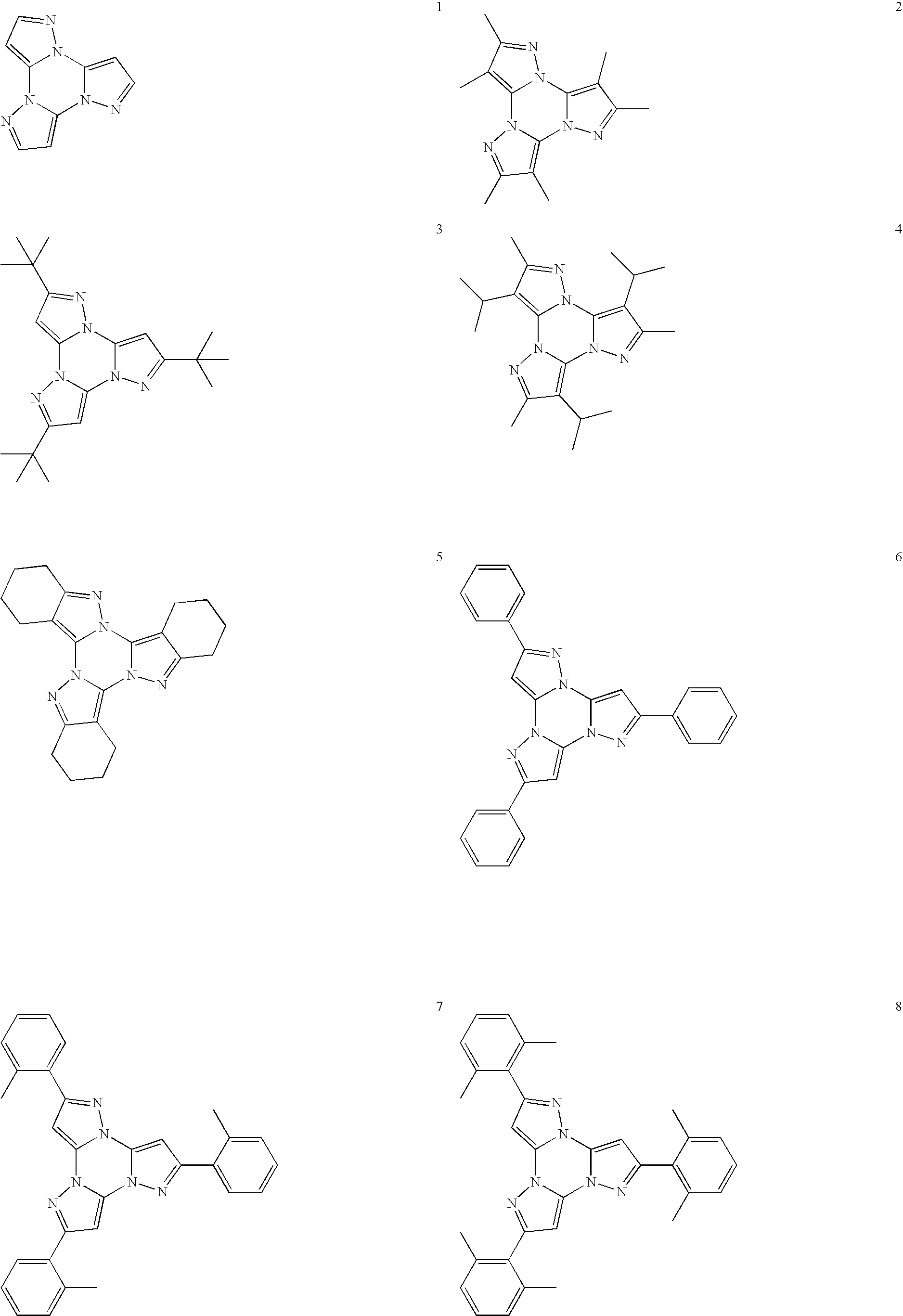

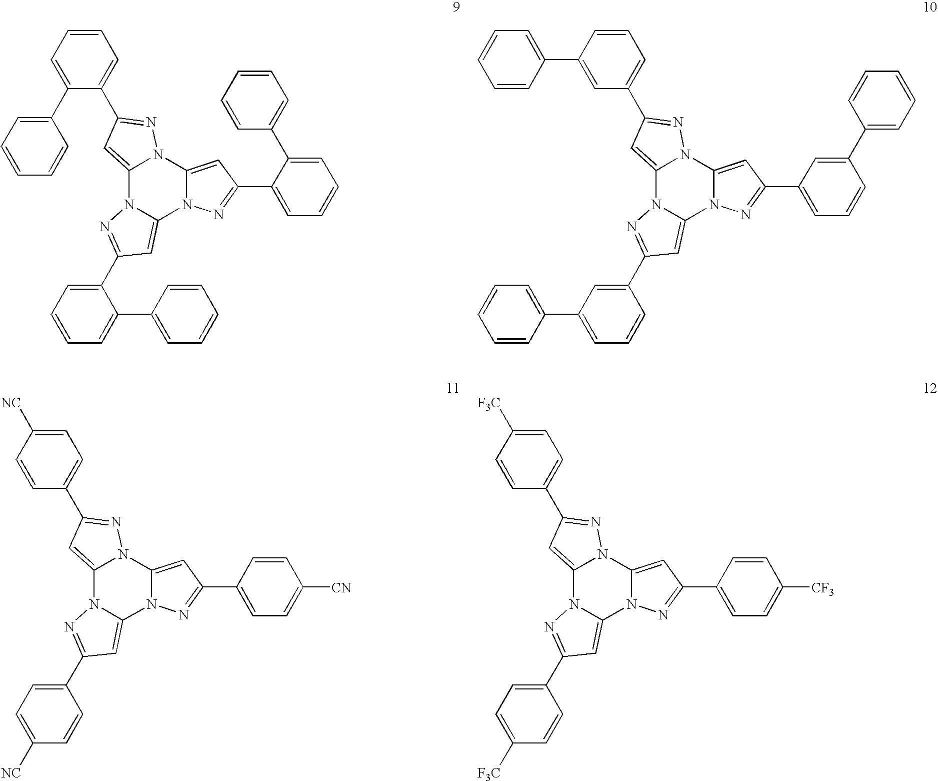

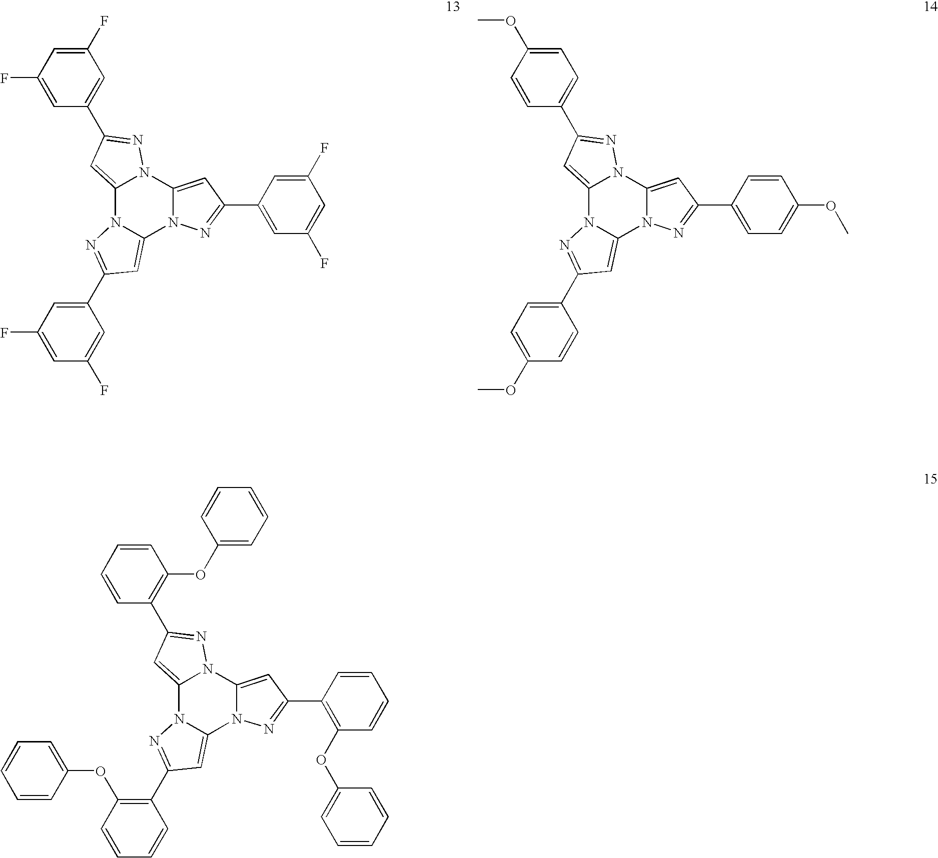

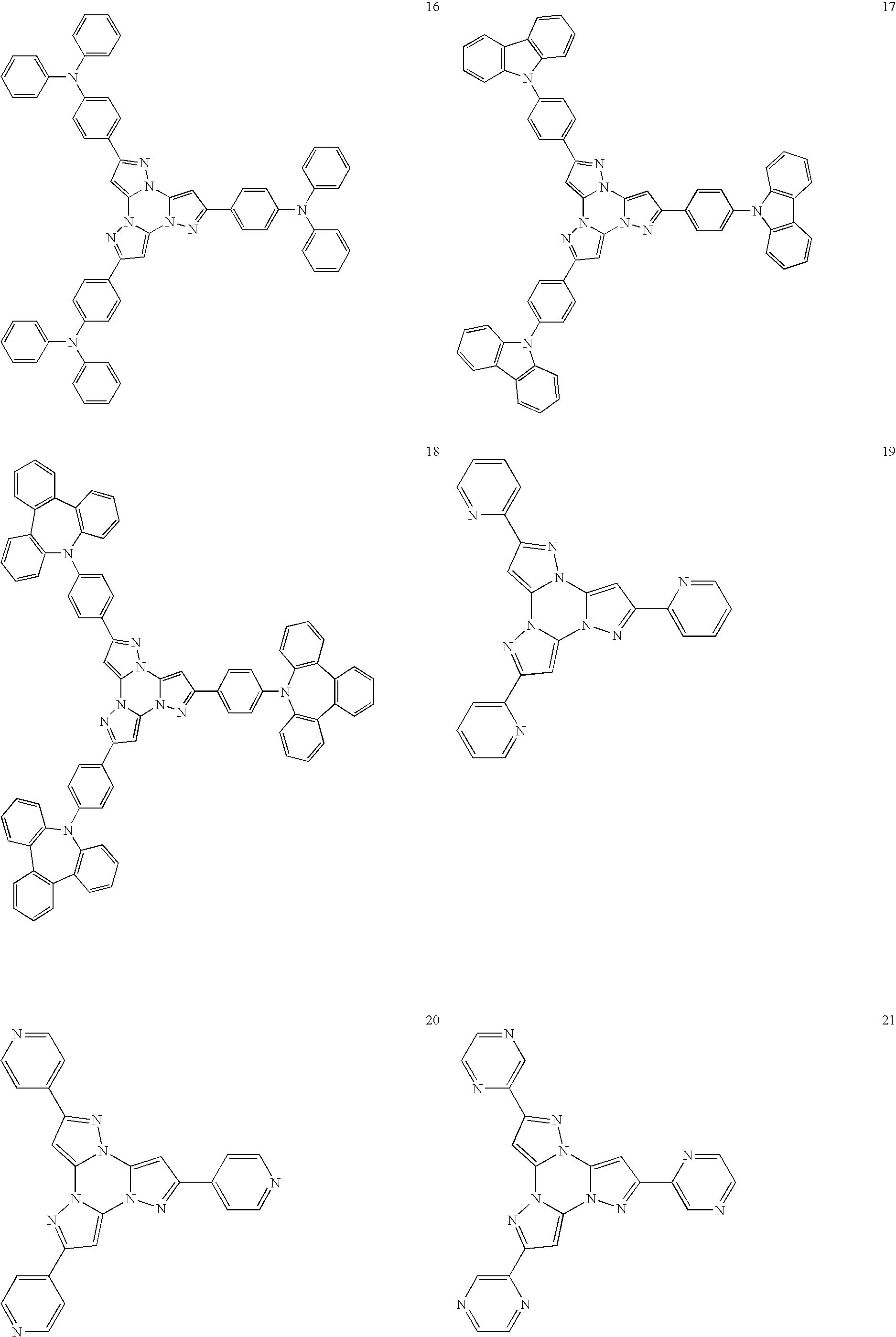

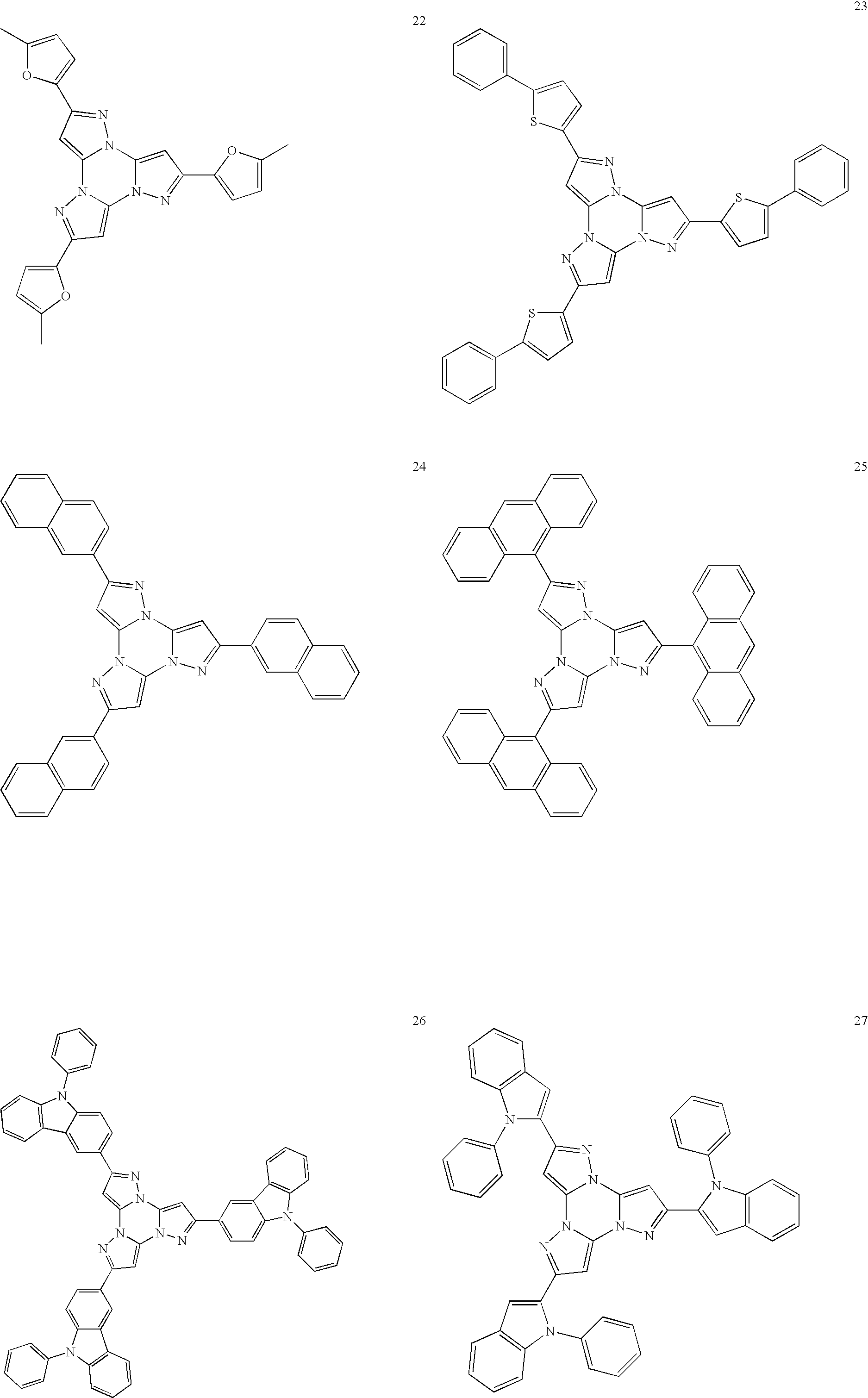

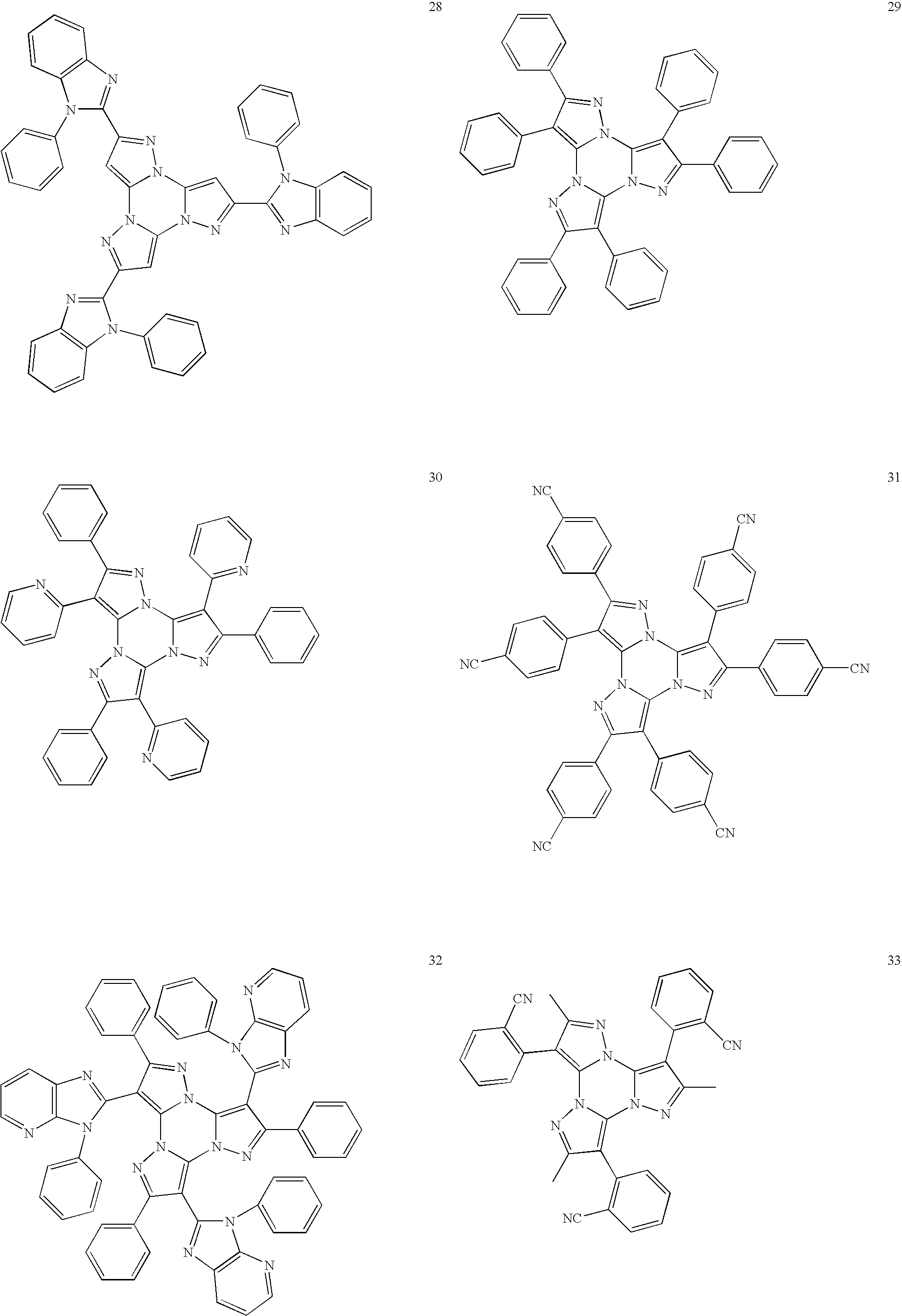

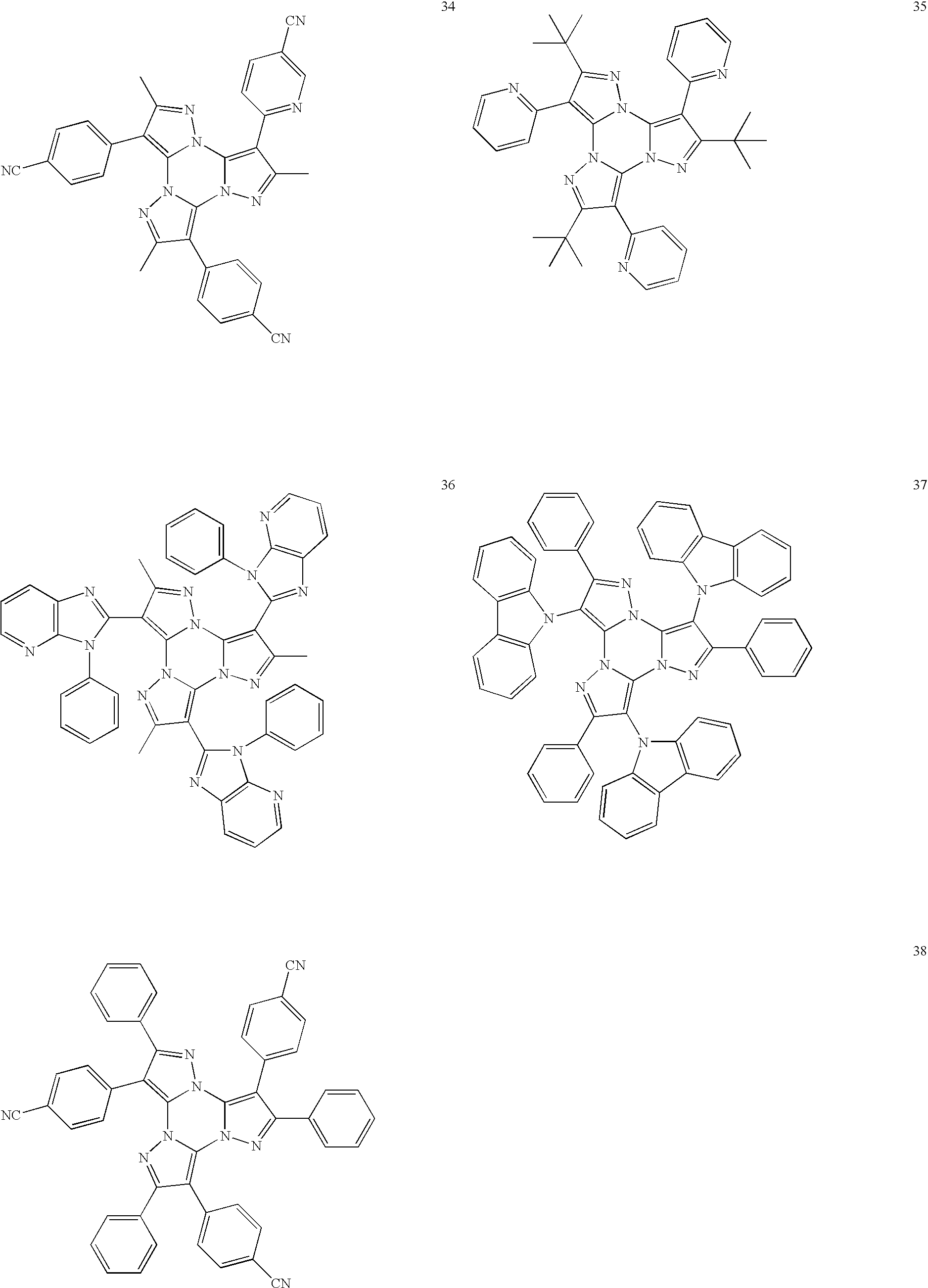

Specific examples of the polymer compound and the oligomer compound containing compounds represented by formula (I) are shown below, but the invention is not limited to these compounds. The polymer compound may be a homopolymer or a copolymer, and the copolymer may be any one of a random copolymer, an alternating copolymer, and a block copolymer. m:n in the formulae denotes a molar ratio of monomer contained in the polymer, mis 1 to 100, n is 0 to 99, and the sum ofm and n is 100.

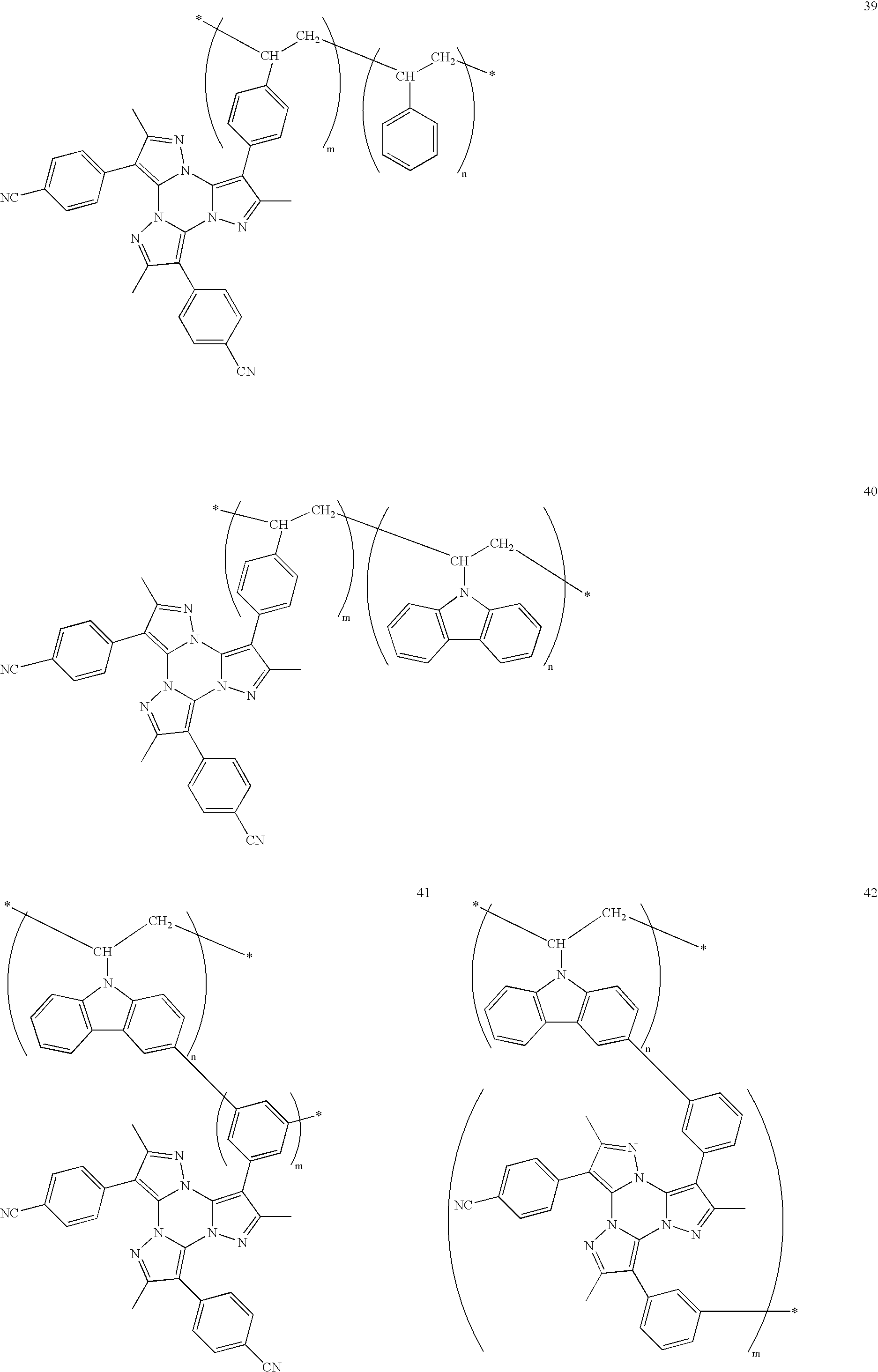

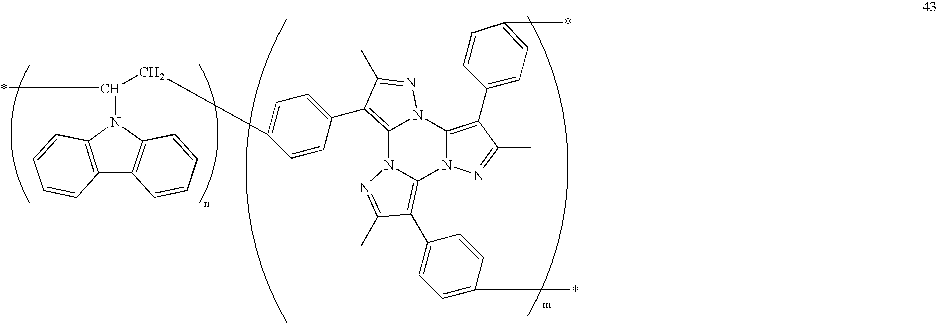

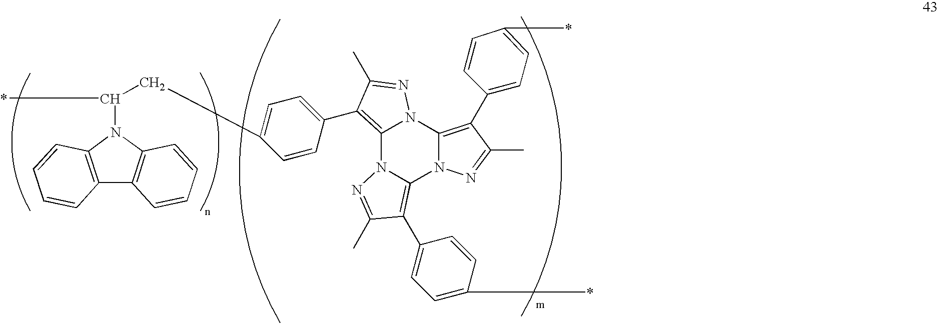

Detailed explanations will be given regarding the each element constituting a device of the invention.

<Substrate>

A substrate to be used in the invention is preferably a substrate which does not scatter or attenuate light emitted from the organic layer. Specific examples include inorganic materials such as yttria-stabilized zirconia (YSZ), and glass; polyesters such as polyethylene terephthalate, polybutylene phthalate, and polyethylene naphthalate; and organic materials such as polystyrene, polycarbonate, polyethersulfone, polyallylate, polyimide, polycycloolefin, norbomene resins, poly(chlorotrifluoroethylene), and the like.

For example, when glass is used for the substrate, it is preferable to use a non-alkali glass as the substrate material, in order to reduce the ions eluting from the glass. Also, when soda lime glass is used, it is preferable to use one having a barrier coat such as silica or the like. When using the organic materials, these are preferably excellent in heat resistance, dimensional stability, solvent resistance, electrical insulating property and processability.

The shape, structure, size and the like of the substrate are not particularly limited and can be appropriately selected in accordance with the intended use, purpose and the like of the light-emitting device. In general, the substrate is preferably a plate-shape. The structure of the substrate may be either a monolayer structure or a layered structure. Further, the substrate may be made of a single material or of two or more materials.

The substrate may be colorless and transparent, or colored and transparent, but a colorless and transparent substrate is preferable from the viewpoint of not scattering or attenuating the light emitted from the organic light-emitting layer.

The substrate can be provided with a layer preventing moisture permeation (gas barrier layer) on the surface or the back surface.

As for the material of the layer preventing moisture permeation (gas barrier layer), inorganic substances such as silicon nitride, silicon oxide or the like are suitably used. The layer preventing moisture permeation (gas barrier layer) can be formed, for example, by high frequency sputtering or the like. When a thermoplastic substrate is used, a hard coat layer, an undercoat layer or the like may be further provided, if necessary.

<Anode>

In general, as for an anode, ones having a function as an electrode for supplying holes to the organic layers would be sufficient. There is no limitation on the shape, structure, size or the like, and the material can be appropriately selected from known electrode materials depending on the intended use and purpose of the light-emitting device. As described above, the anode is typically furnished as a transparent anode.

Examples of the material for the anode include metals, alloys, metal oxides, electroconductive compounds or mixtures thereof. Specific examples of the anode material include electroconductive metal oxides such as tin oxide (ATO, FTO) doped with antimony or fluorine, tin oxide, zinc oxide, indium oxide, indium tin oxide (ITO), and indium zinc oxide (IZO); metals such as gold, silver, chromium, and nickel; as well as mixture or layered product of such metals and electroconductive metal oxides; inorganic electroconductive materials such as copper iodide, and copper sulfate; organic electroconductive materials such as polyaniline, polythiophene, and polypyrrole; and layered product of these substances with ITO. Preferably electroconductive metal oxides and particularly ITO are preferable from the viewpoint of productivity, high electric conductivity, transparency, etc.

The anode can be formed on the substrate according to a method appropriately selected from, in consideration of the suitability to the material constituting the anode, for example, wet methods such as printing and coating, physical methods such as vacuum deposition, sputtering and ion plating, and chemical methods such as CVD and plasma CVD. For example, when ITO is selected as the material for anode, formation of the anode can be carried out by direct current sputtering or high frequency sputtering, vacuum deposition, ion plating or the like.

In the organic electroluminescent device of the invention, the anode can be formed in any part of the light-emitting device selected according to the intended use and purpose thereof, without particular limitation. However, it is preferred that the anode is formed on the substrate. In this case, the anode may be formed on the entire surface of one side of the substrate, or in a part of that surface.

Moreover, patterning in the formation of an anode may be carried out by means of chemical etching involving photolithography or the like, or by means of physical etching involving laser or the like. Further, it may also be carried out by a vacuum deposition or sputtering with masking, or may be carried out by a lift-off method or printing method.

The thickness of the anode can be appropriately selected in accordance with the material constituting the anode and thus cannot be indiscriminately defined. It is generally from 10 nm to 50 μm, and preferably from 50 nm to 20 μm.

The resistance value of the anode is preferably 10³ Ω/sq or less, and more preferably 10² Ω/sq or less. When the anode is transparent, it may be colorless and transparent, or colored and transparent. In order to obtain luminescence from the transparent anode side, the transmissivity is preferably 60% or higher, and more preferably 70% or higher.

In addition, a transparent anode is described in detail in “Tohmeidenkyokumaku No Shintenkai (New Development of Transparent Electrode Films)” supervised by Yutaka Sawada, CMC Inc. (1999), the description of which can be applied to the invention. In case of using a plastic substrate with low heat resistance, it is preferable to employ ITO or IZO and a transparent anode film formed at a low temperature of 150° C. or below.

<Cathode>

In general, as for a cathode, ones having a function as an electrode for injecting electrons to the organic layers would be sufficient. There is no limitation on the shape, structure, size or the like, and the material can be appropriately selected from known electrode materials depending on the intended use and purpose of the light-emitting device.

Examples of the material constituting the cathode include metals, alloys, metal oxides, electroconductive compounds or mixtures thereof. Specific examples include alkali metals (e.g., Li, Na, K, Cs, etc.), alkaline earth metals (e.g., Mg, Ca, etc.), gold, silver, lead, aluminum, sodium-potassium alloys, lithium-aluminum alloys, magnesium-silver alloys, indium, rare earth metals such as ytterbium. They may be used individually, or from the viewpoint of achieving both stability and electron injection property, they may be suitably used in combination of two or more types.

Among these, as for the material constituting the cathode, alkali metals or alkaline earth metals are preferred from the viewpoint of the electron injection property, and materials mainly comprising aluminum are preferred from the viewpoint of excellent storage stability. The materials mainly comprising aluminum are aluminum itself, alloys comprising aluminum and 0.01 to 10% by mass of alkali metals or alkaline earth metals, or mixtures thereof (for example, lithium-aluminum alloys, magnesium-aluminum alloys, etc.).

In addition, the materials for the cathode are described in detail in JP-A-2-15595 and JP-A-5-121172, the descriptions of which are applicable to the invention.

The method of forming a cathode is not particularly limited and can be carried out according to a known method. The cathode can be formed according to a method appropriately selected from, in consideration of the suitability to the material constituting the cathode, for example, wet methods such as printing and coating, physical methods such as vacuum deposition, sputtering and ion plating, and chemical methods such as CVD and plasma CVD. For example, when metal or the like is selected as the material for cathode, formation of the cathode can be carried out by simultaneous or successive sputtering of one, or two or more types thereof.

Moreover, patterning in the formation of a cathode may be carried out by means of chemical etching involving photolithography or the like, or by means of physical etching involving laser or the like. Further, it may also be carried out by a vacuum deposition or sputtering with masking, or may be carried out by a lift-off method or printing method.

In the invention, the cathode can be formed in any part without particular limitation, and may be formed all over the organic layer, or in a part thereon.

Further, a dielectric layer of 0.1 to 5 nm in thickness, comprising a fluoride, oxide or the like of an alkali metal or an alkaline earth metal may be inserted in between the cathode and the organic layer. This dielectric layer can be seen as a type of electron injecting layer. The dielectric layer can be formed by, for example, vacuum deposition, sputtering, ion plating or the like.

The thickness of the cathode can be appropriately selected in accordance with the material constituting the cathode and thus cannot be indiscriminately defined. It is generally from 10 nm to 5 μm, and preferably from 50 nm to 1 μm.

Also, the cathode may be transparent or opaque. In addition, a transparent cathode can be formed by forming a film of a cathode material having a thickness of 1 to 10 nm and further stacking thereon a transparent electroconductive material such as ITO or IZO.

<Organic Layer>

The organic layer of the invention will be described. The device of the invention at least contains an organic layer including a light-emitting layer, and examples of other organic layers other than the organic light-emitting layer include above-mentioned, a hole transport layer, an electron transport layer, a hole blocking layer, a charge blocking layer, a hole injecting layer, an electron injecting layer, and the like.

Formation of Organic Layer

In the organic electroluminescent device of the invention, each layer constituting the organic layer can be suitably formed by a dry film forming method such as a vapor deposition or sputtering, a transcription method, a printing method, or the like.

Light-emitting layer

The light-emitting layer is a layer having the function of emitting light by accepting holes from the anode, the hole injecting layer or the hole transport layer and accepting electrons from the cathode, the electron injecting layer or the electron transport layer upon application of an electric field, and providing a site for rebonding of the holes and the electrons.

The light-emitting layer according to the invention may only contain a light-emitting material, or may contain a mixture of host material and light-emitting material. The light-emitting material may be a fluorescent material or a phosphorescent material, and dopants may be used alone or in combination of two or more kinds thereof. The host material is preferably a charge transport material. The host material may be used alone, or in combination of two or more kinds, and an example includes a mixture constitution comprising an electron transport host material and a hole transport host material. Further, the light-emitting layer may not have the charge transport property, and contain a material not emitting light. The light-emitting layer preferably employs the complex of the invention, and constitutes at least one kind of host material and a complex of the invention.

In addition, the light-emitting layer may be a single layer or a multilayer of two or more layers, and the respective layers may emit lights of different colors.

Examples of the fluorescent material which can be used in the invention include benzoxazole derivatives, benzimidazole derivatives, benzothiazole derivatives, styryl benzene derivatives, polyphenyl derivatives, diphenyl butadiene derivatives, tetraphenyl butadiene derivatives, naphthalimide derivatives, coumarin derivatives, condensed aromatic compounds, perinone derivatives, oxadiazole derivatives, oxazine derivatives, aldazine derivatives, pyralizine derivatives, cyclopentadiene derivatives, bis-styryl anthracene derivatives, quinacridone derivatives, pyrrolopyridine derivatives, thiadiazolopyridine derivatives, cyclopentadiene derivatives, styryl amine derivatives, diketopyrrolopyrrole derivatives, aromatic dimethylidene compounds, various kinds of complexes represented by complexes of 8-quinolinol derivative and complexes of pyrromethane derivative, polymer compounds such as polythiophene, polyphenylene and polyphenylene vinylene, and compounds such as organic silane derivative, etc.

Examples of the phosphorescent material which can be used in the invention, other than the complexes of the invention, include a complex including a transition metal atom or a lanthanoid atom.

The transition metal atom is not particularly limited but may be preferably exemplified by ruthenium, rhodium, palladium, tungsten, rhenium, osmium, iridium and platinum, and more preferably by rhenium, iridium and platinum.

The lanthanoid atom may be exemplified by lanthanum, cerium, praseodymium, neodymium, samarium, europium, gadolinium, terbium, dysprosium, holmium, erbium, thulium, ytterbium and lutetium. Among these lanthanoid atoms, neodymium, europium and gadolinium are preferred.

Examples of the ligand of the complex include the ligands disclosed in G. Wilkinson et al, Comprehensive Coordination Chemistry, Pergamon Press (1987); H. Yersin, “Photochemistry and Photophysics of Coordination Compounds,” Springer-Verlag (1987); Akio Yamamoto, “Yukikinzokukagaku-Kiso to Oyo (Organometallic Chemistry-Fundamentals and Applications),” Shokabo (1982); and the like.

Specific examples of the ligand include preferably halogen ligands (preferably a chlorine ligand), nitrogen-containing heterocyclic ligands (e.g., phenyl pyridine, benzoquinoline, quinolinol, bipyridyl, phenanthroline, etc.), diketone ligands (e.g., acetylacetone, etc.), carboxylic acid ligands (e.g., acetic acid ligand, etc.), carbon monoxide ligand, isonitrile ligand, and cyano ligand, and more preferably nitrogen-containing heterocyclic ligands. The above-mentioned complex may have one transition metal atom in the compound, and may also be a so-called multinuclear complex having two or more of such atoms. It may also contain metal atoms of different types simultaneously.

The phosphorescent material is contained in the light-emitting layer in an amount of preferably from 0.1 to 40% by mass (weight), and more preferably from 0.5 to 20% by mass.

Examples of the host material contained in the light-emitting layer according to the invention include compounds having a carbazole skeleton, a diarylamine skeleton, a pyridine skeleton, a pyrazine skeleton, a triazine skeleton or an arylsilane skeleton, or materials exemplified for the hole injecting layer, the hole transport layer, the electron injecting layer, and the electron transport layer, which will be described later.

The thickness of the light-emitting layer is not particularly limited, but in general it is preferably from 1 nm to 500 nm, more preferably from 5 nm to 200 nm, and even more preferably from 10 nm to 100 nm.

Hole Injecting Layer, Hole Transport Layer

The hole injecting layer and the hole transport layer are layers having a function of accepting holes from the anode or the anode side and transporting them to the cathode side. Specifically, the hole injecting layer and the hole transport layer are preferably the layers containing carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidene type compounds, porphyrin type compounds, organic silane derivatives, carbon or the like.

The thicknesses of the hole injecting layer and the hole transport layer are each preferably 500 run or less, from the viewpoint of lowering the driving voltage.

The thickness of the hole transport layer is preferably from 1 to 500 nm, more preferably from 5 to 200 nm, and even more preferably from 10 to 100 nm. Also, the thickness of the hole injecting layer is preferably from 0.1 to 200 nm, more preferably from 0.5 to 100 nm, and even more preferably from 1 to 100 nm.

The hole injecting layer and the hole transport layer may be of single-layered structure comprising one, or two or more types of the above-mentioned materials, or may be of a multilayered structure including a plurality of layers having the same composition or different compositions.

Electron Injecting Layer, Electron Transport Layer

The electron injecting layer and the electron transport layer are layers having a function of accepting electrons from the cathode or the cathode side and transporting them to the anode side. Specifically, the electron injecting layer and the electron transport layer are preferably layers containing triazole derivatives, oxazole derivatives, oxadiazole derivatives, imidazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, aromatic ring tetracarboxylic acid anhydrides(such as naphthalene and perylene), phthalocyanine derivatives, various complexes such as complexes of 8-quinolinol derivatives, metallophthalocyanines, and complexes having benzoxazole or benzothiazole as a ligand, organic silane derivatives or the like.

The thicknesses of the electron injecting layer and the electron transport layer are each preferably 50 nm or less from the viewpoint of lowering the driving voltage.

The thickness of the electron transport layer is preferably from 1 to 500 nm, more preferably from 5 to 200 nm, and even more preferably from 10 to 100 nm. Also, the thickness of the electron injecting layer is preferably from 0.1 to 200 nm, more preferably from 0.2 to 100 nm, and even more preferably from 0.5 to 50 nm.

The electron injecting layer and the electron transport layer may be of a single-layered structure comprising one or two or more types of the above-mentioned materials, or may be of a multilayered structure including a plurality of layers having the same composition or different compositions.

Hole Blocking Layer The hole blocking layer is a layer having a function of limiting the migration of holes, which are transported to the light-emitting layer from the anode side, to the cathode side. In the invention, the hole blocking layer can be employed as the organic layer adjacent to the cathode side of the light-emitting layer.

Examples of the organic compounds constituting the hole blocking layer include aluminum complexes such as BAlq, triazole derivatives, phenanthroline derivatives such as BCP.

The thickness of the hole blocking layer is preferably from 1 to 500 nm, more preferably from 5 to 200 nm, and even more preferably from 10 to 100 nm.

The hole blocking layer may be of a single-layered structure comprising one or two or more types of the above-mentioned materials, or may be of a multilayered structure including a plurality of layers having the same composition or different compositions.

<Protective Layer>

In the invention, the organic EL device as a whole may be protected by a protective layer.

The materials contained in the protective layer may be any materials having a function of preventing the factors which promote device deterioration such as moisture or oxygen from entering into the device.

Specific examples thereof include metals such as In, Sn, Pb, Au, Cu, Ag, Al, Ti, and Ni, metal oxides such as MgO, SiO, Sio₂, Al₂O₃, GeO, NiO, CaO, BaO, Fe₂O₃, Y₂O₃, and TiO₂, metal nitrides such as SiN^{x} and SiN^{x}O^{y}, metal fluorides such as MgF₂, LiF, AlF₃ and CaF₂, polyethylene, polypropylene, polymethyl methacrylate, polyimide, polyurea, polytetrafluoroethylene, polychlorotrifluoroethylene, polydichlorodifluoroethylene, copolymers of chlorotrifluoroethylene and dichlorodifluoroethylene, copolymers obtainable by a copolymerization of monomer mixture including tetrafluoroethylene and at least one comonomer, fluorine-containing copolymers having a cyclic structure in the copolymer main chain, absorbent materials having an absorption rate of 1% or more, and moisture-resistant materials having an absorption rate of 0.1% or less.

The method of forming the protective layer is not particularly limited, and for example, a vacuum deposition method, sputtering, a reactive sputtering method, an MBE (molecular beam epitaxy) method, a cluster ion beam method, an ion plating method, a plasma polymerization method (high frequency-excited ion plating), a plasma CVD method, a laser CVD method, a thermal CVD method, a gas source CVD method, a coating method, a printing method, and a transcription method.

<Sealing>

Moreover, the device of the invention may be sealed for the entire device using a sealing vessel. Also, a space between the sealing vessel and the device may be sealed with a moisture absorbent or an inactive liquid. The moisture absorbent, though not particularly limited, may be exemplified by barium oxide, sodium oxide, potassium oxide, calcium oxide, sodium sulfate, calcium sulfate, magnesium sulfate, phosphorous pentoxide, calcium chloride, magnesium chloride, copper chloride, cesium fluoride, niobium fluoride, calcium bromide, vanadium bromide, molecular sieves, zeolites, magnesium oxide or the like. The inactive liquid, though not particularly limited, may be exemplified by paraffins, liquid paraffins, fluorine type solvents such as perfluoroalkanes, perfluoroamines and perfluoroethers, chlorine type solvents, and silicone oils.

In the device of the invention, light emission can be achieved by applying a direct current (DC) (it may include an alternating current component, if desired) voltage (typically 2 volts to 15 volts) or a DC current between the anode and the cathode.

As for the method of driving the device of the invention, the methods disclosed in the publications of JP-A-2-148687, JP-A-6-301355, JP-A-5-29080, JP-A-7-134558, JP-A-8-234685 and JP-A-8-241047, in the specifications of Japanese Patent No. 2784615, U.S. Pat. Nos. 5,828,429 and 6,023,308, and the like can be applied.

The light-emitting device of the invention is preferably applied in display devices, displays, backlights, electrophotographs, illuminating light sources, recording light sources, exposing light sources, reading light sources, markers, signboards, interiors, optical communications, etc.

Hereinafter, the present invention will be described in more detail with reference to the following Examples, but the invention is not limited thereto.

### SYNTHETIC EXAMPLE

Synthesis of Exemplary Compounds

The compound shown in the above-mentioned formula (I) may be synthesized using the following process disclosed in Chem. Heterocycl. Compd. Vol. 30, p. 540, 1994. For example, Exemplary Compound 6 may be produced at a yield of 30% by heating phenyl pyrazolon in phosphorus oxychloride. Further, tribromides, which are produced by reacting the Exemplary Compound 6 with bromine in chloroform as disclosed in Chem. Heterocycl. Compd. Vol. 32, p. 789, 1996, may be reacted with a phenylboronic acid using a palladium catalyst as disclosed in J. Am. Chem. Soc. Vol. 124, p. 1162, 2002 to produce Exemplary Compound 29. For example, Exemplary Compound 38 may be produced at the same yield using a 4-cyanophenyl boronic acid instead of the phenylboronic acid.

Hereinafter, the synthesis method of Exemplary Compound 29 will be described in detail. The synthesis of Exemplary Compound 29 was performed as shown in the following scheme.

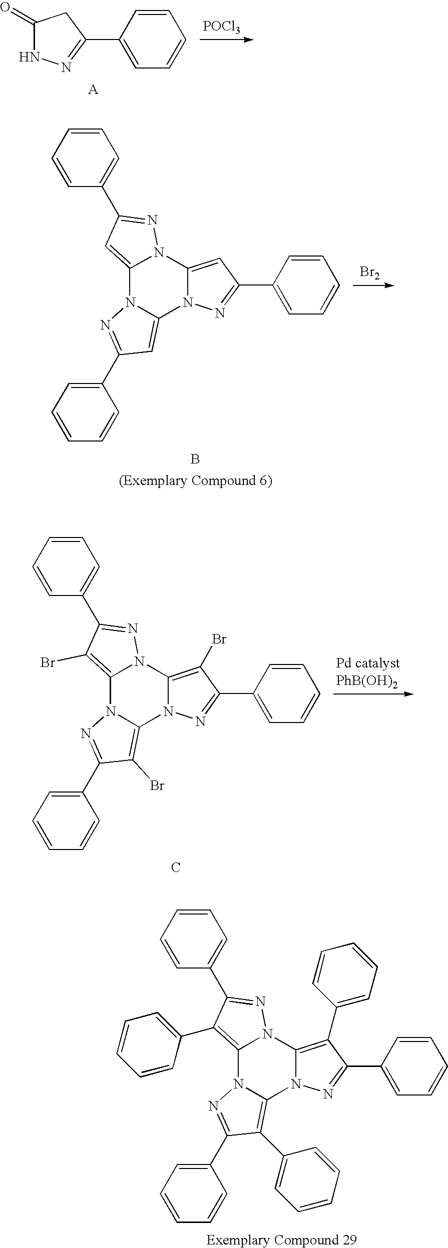

In the above-mentioned production method, in case the defined substituent group is changed under a predetermined synthesis method condition or is improper to perform the method, the production may be easily performed using means for protecting or deprotecting the functional group (for example, Protective Groups in Organic Synthesis, T. W. Greene, John Wiley & Sons Inc. (1981)). If necessary, the change in the order of reaction process, such as use of appropriate substituent groups, may be conducted.

<Preparation and Evaluation of Organic electroluminescent device>

1. Preparation of Organic Electroluminescent Device

(1) Preparation of Organic Electroluminescent Device (TC-11) of the Invention

A glass substrate (manufactured by Geomatec Co., Ltd., having a surface resistance of 10 Ω/sq) of 0.5 mm in thickness and 2.5 cm square with ITO film was put in a cleaning container, ultrasonically cleaned in 2-propanol, and treated by UV ozone for 30 minutes. On this transparent anode (ITO film), following organic compound layers were vapor-deposited in the order by vacuum deposition method.

A deposition rate in Examples of the invention is 0.2 nm/sec, unless otherwise specified. The deposition rate was measured by using a quartz crystal deposition controller CRTM-9000, manufactured by ULVAC, Inc. The thicknesses of films listed below were worked out with a calibration curve prepared on the basis of numerical values obtained from CRTM-9000 and film thicknesses measured using a stylus film thickness measurer “DEKTAK” manufactured by Sloan Co. Ltd.

(Hole transport layer)

NPD: film thickness of 40 nm

(Light-emitting layer)

Mixture layer of 94 mass % Exemplary Compound 17 and 6 mass % Ir(Ppy)₃: film thickness of 20 nm

(Hole block layer)

BCP: film thickness of 6 nm

(Electron transport layer)

Alq: film thickness of 20 nm

Chemical structures of NPD, Ir(ppy)₃, BCP, and Alq are as follows.

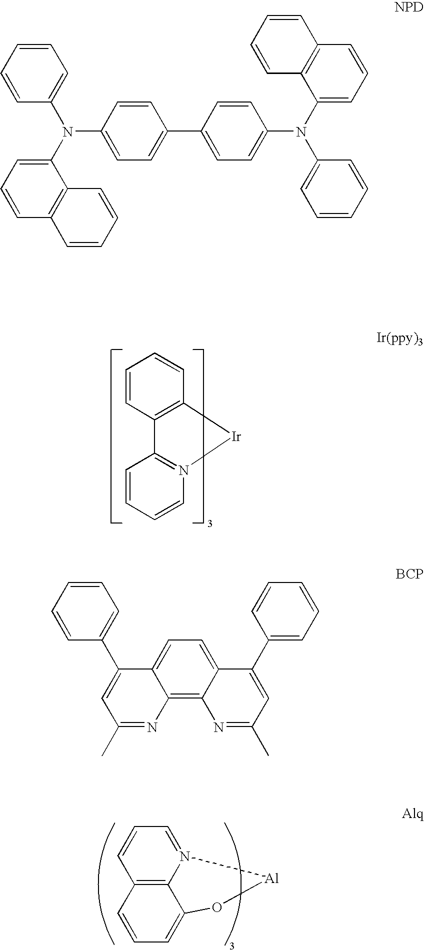

Finally, 0.1 nm of lithium fluoride and metallic aluminum were subsequently deposited by 100 nm to form a cathode. This was then put in a glove box replaced by argon gas without being contacted to the air, and was sealed by using a stainless steel-sealing can and an adhesive of ultraviolet curing type (XNR⁵⁵¹⁶HV, manufactured by Nagase Ciba) to obtain the organic electroluminescent device (TC-11).
(2) Preparation of Organic electroluminescent device (TC-12) of Comparative Example The organic electroluminescent device (TC-12) was prepared in the same manner as in TC-11, except that Exemplary Compound 17 was replaced to a CBP of having the following structure. 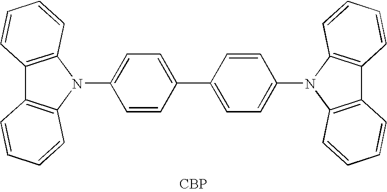
(3) Preparation of Organic Electroluminescent Device (TC-21) of the Invention

The light-emitting layer of 100 nm in thickness and containing PVK (73 wt %), Ir(ppy)₃ (9 wt %), and Exemplary Compound 6 (18 wt %), was formed on the cleaned glass substrate having the ITO electrode according to the spin coating method. An electrode of 150 nm in thickness was formed thereon with an alloy mixed with a magnesium and silver in a 10:1 ratio to obtain the organic electroluminescent device (TC-21) of Example.

(4) Preparation of Organic Electroluminescent Device (TC-22) of Comparative Example

The organic electroluminescent device (TC-22) of the comparative example was produced in the same manner as in TC-21, except that Exemplary Compound 6 was replaced to the following Comparative Compound.

Comparative Compound: 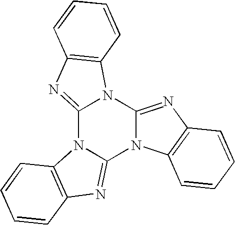
2. Evaluation of Organic Electroluminescent Device
(1) When direct current constant voltage (5 V) was applied to the obtained organic electroluminescent devices described above (TC-11 and TC-12), it was observed to emit green light which is usually emitted by a phosphorescent emitter. Luminous efficiency of TC-11 was higher than that of TC-12, and driving durability of TC-11 was longer than that of TC-12.
(2) When direct current constant voltage (5 V) was applied to the obtained organic electroluminescent devices described above (TC-21 and TC-22), it was observed to emit green light which is usually emitted by a phosphorescent emitter. The maximum luminance of TC-21 was 7000 cd/m², and the maximum luminance of TC-22 was 3000 cd/M².

From the examples described above, it was revealed that highly efficient and highly durable organic electroluminescent devices were obtained by using the compound of the invention.

It will be apparent to those skilled in the art that various modifications and variations can be made to the described embodiments of the invention without departing from the spirit or scope of the invention. Thus, it is intended that the invention cover all modifications and variations of this invention consistent with the scope of the appended claims and their equivalents.

The present application claims foreign priority based on Japanese Patent Application No. JP2005-265609 filed Sep. 13 of 2005, the contents of which is incorporated herein by reference.

What is claimed is:

1. An organic electroluminescent device comprising:
a pair of electrodes; and
at least one organic layer between the pair of electrode, the at least one organic layer including a light-emitting layer, wherein the at least one organic layer contains a compound represented by formula (I): 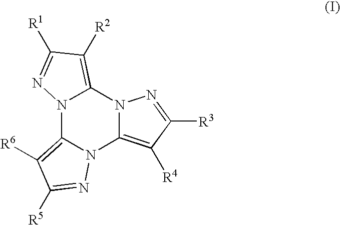
wherein R¹, R², R³, R⁴, R⁵, and R⁶ each independently represents a hydrogen atom or a substituent group; R¹ to R⁶ are same with or different from one another; when R¹ and R² are not hydrogen atoms, R¹ and R² may be bonded to each other to form a ring; when R³ and R⁴ are not hydrogen atoms, R³ and R⁴ may be bonded to each other to form a ring; and when R⁵ and R⁶ are not hydrogen atoms, R⁵ and R⁶ may be bonded to each other to form a ring.

2. The organic electroluminescent device according to claim 1, wherein R¹, R³, and R⁵ each independently represents an aryl group or a heteroaryl group.

3. The organic electroluminescent device according to claim 1, wherein R², R⁴, and R⁶ each independently represents an aryl group or a heteroaryl group.

4. The organic electroluminescent device according to claim 1, wherein R¹ to R⁶ each independently represents an aryl group or a heteroaryl group.

5. The organic electroluminescent device according to claim 1, wherein the light-emitting layer contains the compound represented by formula (I).

6. The organic electroluminescent device according to claim 1, wherein the at least one organic layer includes at least one of an electron injecting layer and an electron transport layer, the at least one of the electron injecting layer and the electron transport layer contains the compound represented by formula (I).

7. The organic electroluminescent device according to claim 1, wherein the at least one organic layer includes at least one of a hole injecting layer and a hole transport layer, the at least one of the hole injecting layer and the hole transport layer contains the compound by formula (I).

8. The organic electroluminescent device according to claim 1, wherein the light-emitting layer contains at least one light-emitting material and at least two host materials, and at least one of the at least two host materials is the compound represented by formula (I).

9. The organic electroluminescent device according to claim 1, wherein the light-emitting layer contains at least one phosphorescent material, and the at least one organic layer contains the compound represented by formula (I).

10. The organic electroluminescent device according to claim 9, wherein the light-emitting layer contains at least one metal complex having a tetradentate ligand as the phosphorescent material.
